(19) United States
(12) Patent Application Publication
(10) Pub. No.: US 2018/0053659 A1
(43) Pub. Date: Feb. 22, 2018

(54) METHODS AND APPARATUS FOR DEPOSITION PROCESSES

(71) Applicant: APPLIED MATERIALS, INC., Santa Clara, CA (US)

(72) Inventors: Tapash CHAKRABORTY, Mumbai (IN); Prerna GORADIA, Mumbai (IN); Robert Jan VISSER, Menlo Park, CA (US)

(21) Appl. No.: 15/552,754

(22) PCT Filed: Feb. 25, 2016
(86) PCT No.: PCT/US2016/019597

§ 371 Date: Aug. 22, 2017

(30) Foreign Application Priority Data
Feb. 26, 2015 (IN) 553/DEL/2015

(51) Int. Cl. H01L 21/285; C23C 16/24; C30B 25/16; C23C 16/30; C23C 16/455; C30B 29/06; C30B 29/52; H01L 21/02

(52) U.S. Cl. CPC H01L 21/28518; C23C 16/24; C30B 25/165; C23C 16/30; H01L 21/02636; C30B 29/06; C30B 29/52; H01L 21/0262; C23C 16/45523

(57) ABSTRACT

Methods for selective dielectric deposition using self-assembled monolayer (SAM) are provided herein. A method of selectively depositing a low-k dielectric layer atop a substrate having an exposed silicon surface and an exposed silicon-containing surface, includes: (a) growing an organosilane based self-assembled monolayer atop the exposed silicon-containing surface, wherein the organosilane based self-assembled monolayer is thermally stable at a first temperature of greater than about 300 degrees Celsius; and (b) selectively depositing a low-k dielectric layer atop the exposed silicon surface of the substrate, wherein the organosilane based self-assembled monolayer inhibits deposition of the low-k dielectric layer atop the silicon-containing surface.

### FIELD

Embodiments of the present disclosure generally relate to methods for selective dielectric deposition using self-assembled monolayers.

### BACKGROUND

Selective atomic layer deposition (ALD) and chemical vapor deposition (CVD) processes can advantageously reduce the number of steps and cost involved in conventional lithography while keeping up with the pace of device dimension shrinkage. Selective silicon based dielectric deposition in a metal dielectric pattern is of high potential value in back-end of line (BEOL) applications. Some alternative selective silicon based dielectric deposition techniques that have emerged are template-controlled growth, holographic based lithography, and the like. However, none of these alternative techniques provide a complete solution due to limitations like throughput, scale, defect issues, etc.

Accordingly, the inventors have developed improved methods and apparatus for selective dielectric deposition using self-assembled monolayer as sacrificial and nucleation inhibition layer.

### SUMMARY

Methods for selective deposition using self-assembled monolayer (SAM) are provided herein. In some embodiments, a method of selectively depositing a low-k dielectric layer atop a substrate having an exposed silicon surface and an exposed silicon-containing surface, includes: (a) growing an organosilane based self-assembled monolayer atop the exposed silicon-containing surface, wherein the organosilane based self-assembled monolayer is thermally stable at a first temperature of greater than about 300 degrees Celsius; and (b) selectively depositing a low-k dielectric layer atop the exposed silicon surface of the substrate, wherein the organosilane based self-assembled monolayer inhibits deposition of the low-k dielectric layer atop the silicon-containing surface.

In some embodiments, a method of selectively depositing a layer atop a substrate having an exposed metal surface and an exposed silicon-containing surface, includes: (a) growing a first self-assembled monolayer atop the exposed metal surface; (b) growing a second self-assembled monolayer atop the exposed silicon-containing surface, wherein the second self-assembled monolayer is organosilane based; (c) heating the substrate to a temperature of about 200 to about 300 degrees Celsius to remove the first self-assembled monolayer from atop the exposed metal surface; (d) selectively depositing a layer atop the exposed metal surface, wherein the layer is a low-k dielectric layer or a metal layer; and (e) heating the substrate to a temperature of about 500 to about 1000 degrees Celsius to remove the second self-assembled monolayer from atop the exposed silicon-containing surface.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. The appended drawings illustrate only typical embodiments of the disclosure and are therefore not to be considered limiting of the scope, for the disclosure may admit to other equally effective embodiments.

FIG. 1 depicts a process chamber suitable for performing a chemical vapor deposition process or atomic layer deposition process in accordance with some embodiments of the present disclosure.

FIG. 2 depicts a flowchart of a method of selective deposition in accordance with some embodiments of the present disclosure.

FIGS. 3A-3D are illustrative cross-sectional views of the substrate during different stages of the processing sequence of FIG. 2 in accordance with some embodiments of the present disclosure.

FIG. 4 is a flow diagram of a method of selective deposition in accordance with some embodiments of the present disclosure.

FIGS. 5A-5F are illustrative cross-sectional views of the substrate during different stages of the processing sequence of FIG. 4 in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods for selective dielectric deposition using self-assembled monolayer (SAM) are provided herein. In some embodiments, the inventive methods described herein advantageously provide an innovative method of selective dielectric deposition or selective metal deposition using self-assembled monolayers. Self-assembled monolayers (SAM) can selectively grow on patterned substrate and enable selective deposition by inhibiting nucleation selectively.

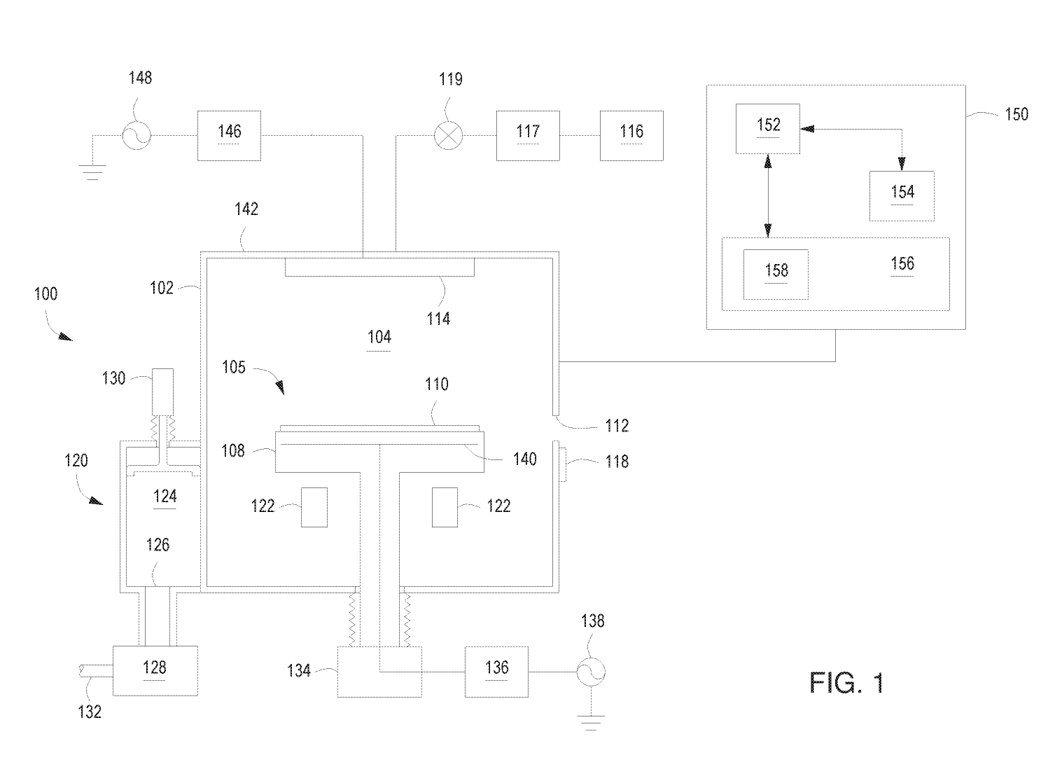

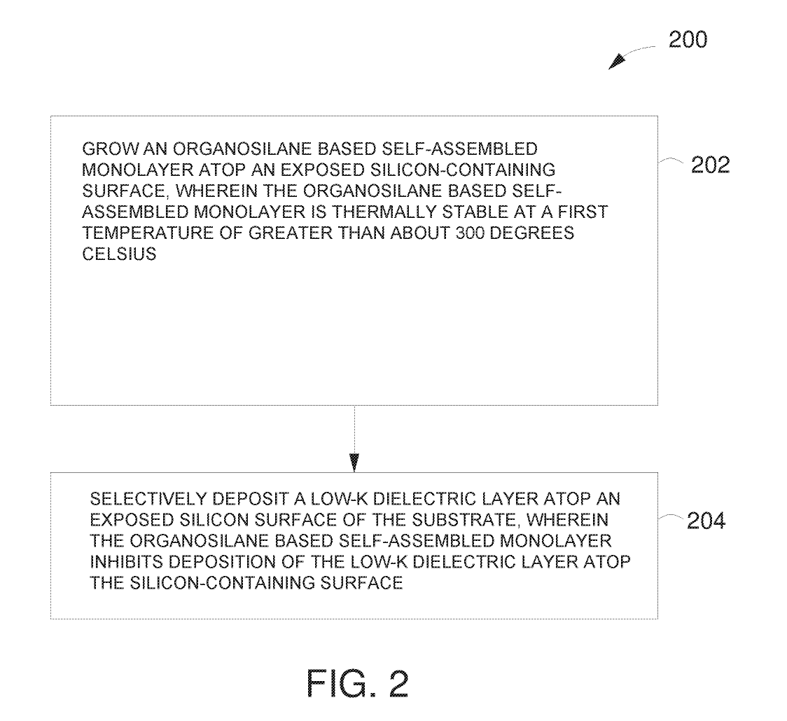

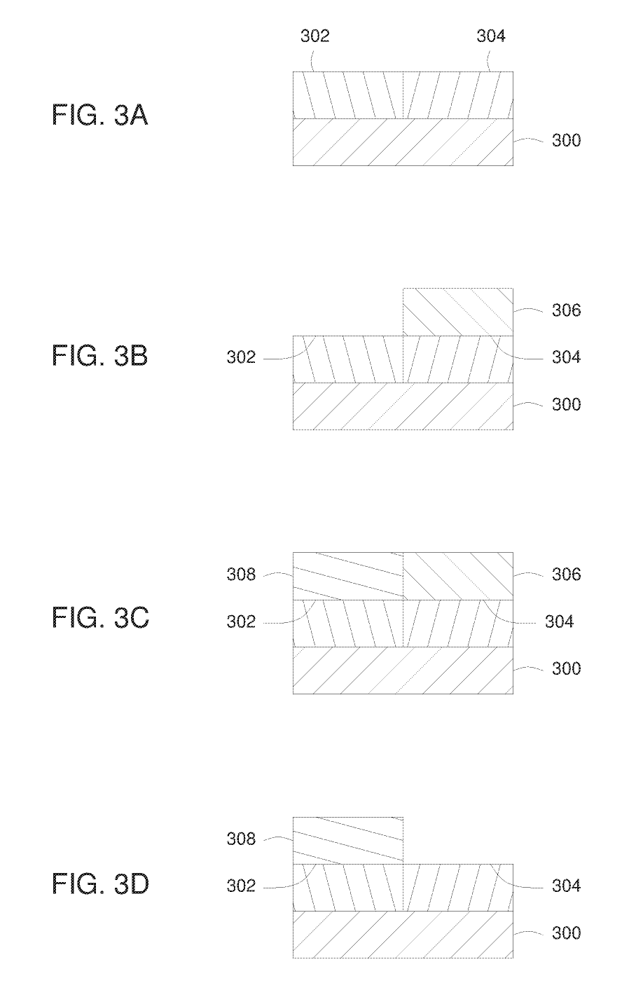

FIG. 2 is a flow diagram of a method 200 of processing a substrate having an exposed silicon surface and an exposed silicon-containing surface in accordance with some embodiments of the present disclosure. FIGS. 3A-3D are illustrative cross-sectional views of the substrate during different stages of the processing sequence of FIG. 2 in accordance with some embodiments of the present disclosure. The inventive methods may be performed in process chambers configured for atomic layer deposition (ALD) or chemical vapor deposition (CVD), such as the process chamber discussed below with respect to FIG. 1.

The method 200 is performed on a substrate 300, as depicted in FIG. 3A, having an exposed silicon surface 302 and an exposed silicon-containing surface 304. The silicon-containing surface 304 is not the same as silicon surface 302. The silicon-containing surface 304, may be silicon dioxide, silicon nitride, or silicon oxynitride (SiON). In some embodiments, the substrate 300 may be a semiconductor wafer, such as a 200 or 300 mm semiconductor wafer. Other size and geometry substrates may also be used.

The method 200 begins at 202 and as depicted in FIG. 3B, by depositing an organosilane based self-assembled monolayer (self-assembled monolayer 306) atop the exposed silicon-containing surface 304. The self-assembled monolayer 306 is chosen to be thermally stable at a first temperature of greater than about 300 degrees Celsius, for example about 300 to about 500 degrees Celsius. By selecting a self-assembled monolayer 306 that is thermally stable at the first temperature, a subsequent deposition of the dielectric layer, via a chemical vapor deposition (CVD) or atomic layer deposition (ALD) process, typically performed at a temperature of less than 300 degrees Celsius will not decompose the self-assembled monolayer 306.

Growing the organosilane based self-assembled monolayer 306 comprises exposing the substrate 300 to a solution comprising a liquid organosilane. Suitable organosilanes have long alkyl chains to form a compact, defect free, thermally stable, and chemically inert barrier which can be removed cleanly at a later stage. Suitable organosilanes have C-8 to C-30 chains, including all the corresponding homologues with C-8 to upward of C-30 chains. Exemplary suitable organosilanes include, but are not limited to, octadecyltrichlorosilane (ODTS), trimethoxy(octadecyl)silane (ODTMS), chloro(dimethyl)octadecylsilane (CDODS), or trichloro(1H, 1H, 2H, 2H-perfluorooctyl)silane (PFTS). One of the criteria listed above of choosing the organosilane molecule is the thermal stability of the self-assembled monolayer. Selecting a self-assembled monolayer that is thermally stable at the deposition temperature of the subsequently deposited dielectric layer avoids decomposition of the self-assembled monolayer 306 at the deposition temperature of the subsequently deposited dielectric layer. For example, the thermal stability of ODTS on silicon dioxide (SiO₂) is at least up to 500 degree Celsius. Accordingly, an ODTS self-assembled monolayer will not decompose during the deposition of dielectric material such as silicon dioxide (SiO₂) or silicon nitride (SiN) via an ALD process. Thus, the thermal stability of ODTS-SiO2 SAM expands the temperature compatibility limit.

The solution further comprises a solvent, such as toluene, hexane, cyclohexane, or diethylether. In some embodiments, the solution comprises the solvent having about 1 millimol to about 10 millimol of organosilane. The substrate 300 is dipped in the solution for about 2 to about 3 hours to form the self-assembled monolayer 306 atop the exposed silicon-containing surface 304. The organosilane molecules have a chemical affinity (i.e. are reactive and selective) to the oxide in a silicon oxide (SiO₂) surface, or the nitride in a silicon nitride (SiN) surface or the oxide and nitride in a silicon oxynitride (SiON) surface. Thus, the self-assembled monolayer 306 will only form on the exposed silicon-containing surface 304 but not on the exposed silicon surface 302. The substrate 300 is rinsed with a solvent, for example a solvent listed above, after depositing the self-assembled monolayer 306 to remove any unabsorbed organosilane molecules.

In some embodiments, the exposed silicon surface 302 may have a native oxide layer formed atop the exposed silicon surface 302. In some embodiments, the native oxide layer is removed prior to depositing the self-assembled monolayer 306. In embodiments where a native oxide layer is to be removed from the substrate, a SICONI™ Pre-clean process may be performed in a suitable chamber, such as a process chamber that utilizes SICONI™ technology available from Applied Materials, Inc., of Santa Clara, Calif. In such embodiments, the substrate 300 may be exposed to a fluorine containing precursor and a hydrogen containing precursor in a two part dry chemical clean process. In some embodiments, the fluorine containing precursor may comprise nitrogen trifluoride (NF₃), hydrogen fluoride (HF), diatomic fluorine (F₂), monatomic fluorine (F) and fluorine-substituted hydrocarbons, combinations thereof, or the like. In some embodiments, the hydrogen containing precursors may comprise atomic hydrogen (H), diatomic hydrogen (H2), ammonia (NH3), hydrocarbons, incompletely halogen-substituted hydrocarbons, combinations thereof, or the like. In some embodiments, the first part in the two part process may comprise using a remote plasma source to generate an etchant species (e.g., ammonium fluoride (NHF₄)) from the fluorine containing precursor (e.g., nitrogen trifluoride (NF₃)) and the hydrogen containing precursor (e.g., ammonia (NH₃)). By using a remote plasma source, damage to the substrate may be minimized. The etchant species are then introduced into the pre-clean chamber and condensed into a solid by-product on the substrate surface through a reaction with native oxide layer. An in-situ anneal may then be performed to decompose the by-product. The by-product then sublimates and may be removed from the substrate surface via a flow of gas and pumped out of the pre-clean chamber.

Next, at 204 and as depicted in FIG. 3C, a low-k dielectric layer 308 is selectively depositing atop the exposed silicon surface 302 of the substrate 300. In some embodiments, the low-k dielectric layer is deposited via any suitable atomic layer deposition process or a chemical layer deposition process. The presence of the self-assembled monolayer 306 atop the silicon-containing surface 304 inhibits formation of the low-k dielectric layer on the silicon-containing surface 304 while the thermal stability of the self-assembled monolayer 306 prevents decomposition of the self-assembled monolayer 306 at the deposition temperatures of the low-k dielectric layer (e.g. less than about 300 degrees Celsius). The low-k dielectric layer 308 may include any low-k dielectric material suitable for semiconductor device fabrication. For example, in some embodiments, the low-k dielectric layer 308 may comprise a silicon containing material, for example, such as silicon oxide (SiO2). As used herein, the low-k dielectric layer 308 may have a low-k value of less than about 3.9 (for example, about 2.5 to about 3.5).

Next, and as depicted in FIG. 3D, the substrate 300 is heated to a temperature of greater than about 500 degrees Celsius, for example about 500 to about 1000 degrees Celsius, to remove the self-assembled monolayer 306 from atop the exposed silicon-containing surface 304. Following removal of the self-assembled monolayer 306 the method 200 ends and the substrate may undergo further processing as necessary for completion of a semiconductor device, such as a field effect transistor (FET), a fin field effect transistor (FinFET), a flash memory device, a 3D FINFET device, or the like.

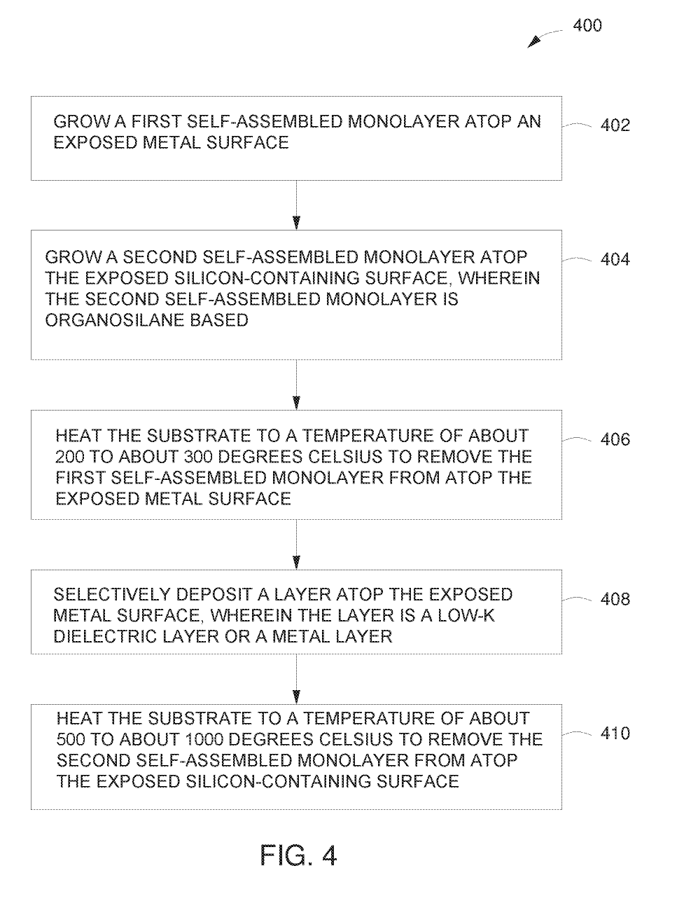

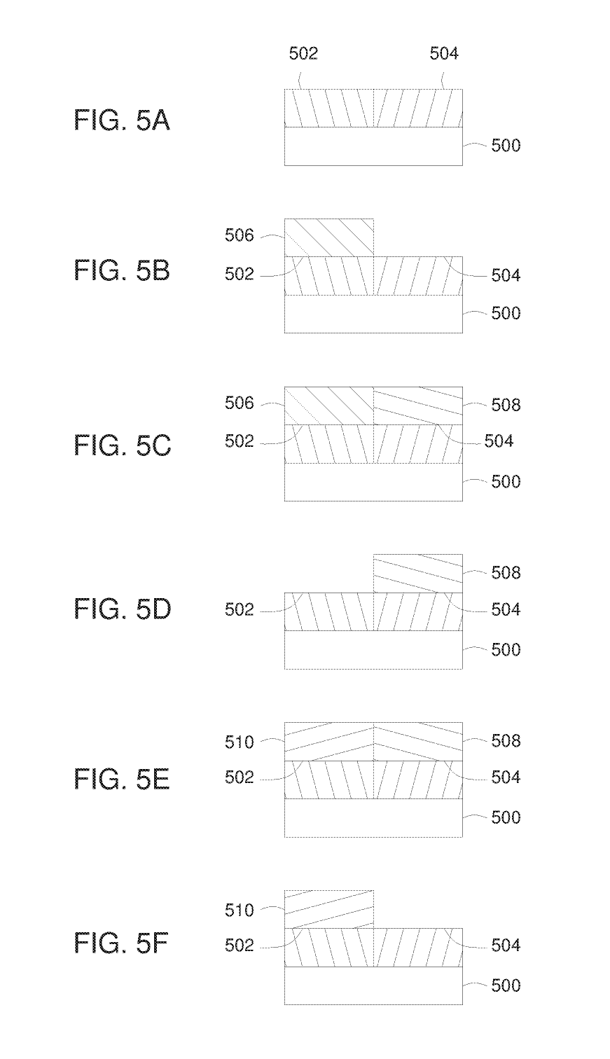

FIG. 4 is a flow diagram of a method 400 of processing a substrate having an exposed metal surface and an exposed silicon-containing surface in accordance with some embodiments of the present disclosure. FIGS. 5A-5F are illustrative cross-sectional views of the substrate during different stages of the processing sequence of FIG. 4 in accordance with some embodiments of the present disclosure. The inventive methods may be performed in process chambers configured for atomic layer deposition (ALD) or chemical vapor deposition (CVD), such as the process chamber discussed below with respect to FIG. 1.

The method 400 is performed on a substrate 500, as depicted in FIG. 5A, having an exposed metal surface 502 and an exposed silicon-containing surface 504. The exposed metal surface 502 may be copper or cobalt. The silicon-containing surface 504 may be silicon dioxide, silicon nitride, or silicon oxynitride (SiON). In some embodiments, the substrate 500 may be a semiconductor wafer, such as a 200 or 300 mm semiconductor wafer. Other size and geometry substrates may also be used.

The method begins at 402 and as depicted in FIG. 5B by growing a first self-assembled monolayer 506 atop the exposed metal surface 502. Growing the first self-assembled monolayer 506 comprises dipping the substrate 500 in a solution for about 2 to about 3 hours to form the first self-assembled monolayer 506 atop the exposed metal surface 502. The solution comprises a solvent and long chain (i.e. C-8 to C-30 chains, including all the corresponding homologues with C-8 to upward of C-30 chains) alkyl thiols, long chain organophosphonic acids, or long chain sulfonic acids (i.e. SAM precursors). Exemplary suitable SAM precursors include, but are not limited to, octadecylthiol, octadecylphosphonic acid, and octadecylsulfonic acid. Exemplary solvents include, but are not limited to, ethanol or tetrahydrofuran (THF). In some embodiments, the solution comprises the solvent having about 1 millimol to about 10 millimol of SAM precursors. The SAM precursor molecules have a chemical affinity (i.e. are reactive and selective) to the metal surface and, thus, will only form the first self-assembled monolayer 506 on the exposed metal surface 502 but not on the exposed silicon-containing surface 504. The substrate 500 is then rinsed with a solvent, for example a solvent listed above, after depositing the first self-assembled monolayer 506 to remove any unabsorbed SAM precursor molecules

Next, at 404 and as depicted in FIG. 5C, a second self-assembled monolayer 508 is depositing atop the exposed silicon-containing surface 504. The second self-assembled monolayer 508 is organosilane based as described above with respect to method 200. The second self-assembled monolayer 508 is deposited as described above with respect to method 200. However, the second self-assembled monolayer 508 is not selective to just the silicon-containing surface 504 and can react with the exposed metal surface 502. Accordingly, the presence of the first self-assembled monolayer 506 prevents reaction of the second self-assembled monolayer 508 with the exposed metal surface 502.

Next, at 406 and as depicted in FIG. 5D, the substrate 500 is heated to a temperature of about 200 to about 300 degrees Celsius to remove the first self-assembled monolayer 506 from atop the metal surface 502. The second self-assembled monolayer 508 is thermally stable at a higher temperature than the first self-assembled monolayer 506. Accordingly, the second self-assembled monolayer 508 will not decompose at the temperature at which the first self-assembled monolayer 506 is removed from atop the metal surface 502.

Next, at 408 and as depicted in FIG. 5E, a layer 510, is selectively depositing atop the exposed metal surface 502. In some embodiments, the layer 510 is a low-k dielectric layer. The low-k dielectric layer may include any low-k dielectric material suitable for semiconductor device fabrication. For example, in some embodiments, the low-k dielectric layer may comprise a silicon containing material, for example, such as silicon oxide (SiO2). As used herein, the low-k dielectric layer 308 may have a low-k value of less than about 3.9 (for example, about 2.5 to about 3.5). In some embodiments, the layer 510 is a metal layer such as copper, tungsten, titanium or nickel. In some embodiments, the layer 510 is deposited via any suitable atomic layer deposition process or a chemical layer deposition process. The presence of the second self-assembled monolayer 508 atop the silicon-containing surface 504 inhibits formation of the layer 510 on the silicon-containing surface 504 while the thermal stability of the second self-assembled monolayer 508 prevents decomposition of the second self-assembled monolayer 508 at the deposition temperatures of the layer 510.

Next, at 410 and as depicted in FIG. 5F, the substrate 500 is heating to a temperature of about 500 to about 1000 degrees Celsius to remove the second self-assembled monolayer 508 from atop the silicon-containing surface 504. Following removal of the second self-assembled monolayer 508 the method 400 ends and the substrate may undergo further processing as necessary for completion of a semiconductor device, such as a field effect transistor (FET), a fin field effect transistor (FinFET), a flash memory device, a 3D FINFET device, or the like

FIG. 1 depicts a schematic diagram of an illustrative apparatus 100 of the kind that may be used to practice embodiments of the disclosure as discussed herein. The apparatus 100 may comprise a controller 150 and a process chamber 102 having an exhaust system 120 for removing excess process gases, processing by-products, or the like, from the inner volume 105 of the process chamber 102. Exemplary process chambers may include any of several process chambers configured for atomic layer deposition (ALD) or chemical vapor deposition (CVD), available from Applied Materials, Inc. of Santa Clara, Calif. Other suitable process chambers from other manufacturers may similarly be used.

The process chamber 102 has an inner volume 105 that may include a processing volume 104. The processing volume 104 may be defined, for example, between a substrate support 108 disposed within the process chamber 102 for supporting a substrate 110 thereupon during processing and one or more gas inlets, such as a showerhead 114 and/or nozzles provided at predetermined locations. In some embodiments, the substrate support 108 may include a mechanism that retains or supports the substrate 110 on the surface of the substrate support 108, such as an electrostatic chuck, a vacuum chuck, a substrate retaining clamp, or the like (not shown). In some embodiments, the substrate support 108 may include mechanisms for controlling the substrate temperature (such as heating and/or cooling devices, not shown) and/or for controlling the species flux and/or ion energy proximate the substrate surface.

For example, in some embodiments, the substrate support 108 may include an RF bias electrode 140. The RF bias electrode 140 may be coupled to one or more bias power sources (one bias power source 138 shown) through one or more respective matching networks (matching network 136 shown). The one or more bias power sources may be capable of producing up to 1200 W or RF energy at a frequency of about 2 MHz to about 60 MHz, such as at about 2 MHz, or about 13.56 MHz, or about 60 Mhz. In some embodiments, two bias power sources may be provided for coupling RF power through respective matching networks to the RF bias electrode 140 at respective frequencies of about 2 MHz and about 13.56 MHz. The at least one bias power source may provide either continuous or pulsed power. In some embodiments, the bias power source alternatively may be a DC or pulsed DC source.

The substrate 110 may enter the process chamber 102 via an opening 112 in a wall of the process chamber 102. The opening 112 may be selectively sealed via a slit valve 118, or other mechanism for selectively providing access to the interior of the chamber through the opening 112. The substrate support 108 may be coupled to a lift mechanism 134 that may control the position of the substrate support 108 between a lower position (as shown) suitable for transferring substrates into and out of the chamber via the opening 112 and a selectable upper position suitable for processing. The process position may be selected to maximize process uniformity for a particular process. When in at least one of the elevated processing positions, the substrate support 108 may be disposed above the opening 112 to provide a symmetrical processing region.

The one or more gas inlets (e.g., the showerhead 114) may be coupled to a gas supply 116 for providing one or more process gases through a mass flow controller 117 into the processing volume 104 of the process chamber 102. In addition, one or more valves 119 may be provided to control the flow of the one or more process gases. The mass flow controller 117 and one or more valves 119 may be used individually, or in conjunction to provide the process gases at predetermined flow rates at a constant flow rate, or pulsed (as described above).

Although a showerhead 114 is shown in FIG. 3, additional or alternative gas inlets may be provided such as nozzles or inlets disposed in the ceiling or on the sidewalls of the process chamber 102 or at other locations suitable for providing gases to the process chamber 102, such as the base of the process chamber, the periphery of the substrate support, or the like.

The apparatus 100 may utilize capacitively coupled RF energy for plasma processing. For example, the process chamber 102 may have a ceiling 142 made from dielectric materials and a showerhead 114 that is at least partially conductive to provide an RF electrode (or a separate RF electrode may be provided). The showerhead 114 (or other RF electrode) may be coupled to one or more RF power sources (one RF power source 148 shown) through one or more respective matching networks (matching network 146 shown). The one or more plasma sources may be capable of producing up to about 3,000 W, or in some embodiments, up to about 5,000 W, of RF energy at a frequency of about 2 MHz and/or about 13.56 MHz or a high frequency, such as 27 MHz and/or 60 MHz. The exhaust system 120 generally includes a pumping plenum 124 and one or more conduits that couple the pumping plenum 124 to the inner volume 105 (and generally, the processing volume 104) of the process chamber 102.

A vacuum pump 128 may be coupled to the pumping plenum 124 via a pumping port 126 for pumping out the exhaust gases from the process chamber via one or more exhaust ports (two exhaust ports 122 shown). The vacuum pump 128 may be fluidly coupled to an exhaust outlet 132 for routing the exhaust to appropriate exhaust handling equipment. A valve 130 (such as a gate valve, or the like) may be disposed in the pumping plenum 124 to facilitate control of the flow rate of the exhaust gases in combination with the operation of the vacuum pump 128. Although a z-motion gate valve is shown, any suitable, process compatible valve for controlling the flow of the exhaust may be utilized.

To facilitate control of the process chamber 102 as described above, the controller 150 may be any form of general-purpose computer processor that can be used in an industrial setting for controlling various chambers and sub-processors. The memory, or computer-readable medium, 156 of the CPU 152 may be one or more of readily available memory such as random access memory (RAM), read only memory (ROM), floppy disk, hard disk, or any other form of digital storage, local or remote. The support circuits 154 are coupled to the CPU 152 for supporting the processor in a conventional manner. These circuits include cache, power supplies, clock circuits, input/output circuitry and subsystems, and the like.

The inventive methods disclosed herein may generally be stored in the memory 156 as a software routine 158 that, when executed by the CPU 152, causes the process chamber 102 to perform processes of the present disclosure. The software routine 158 may also be stored and/or executed by a second CPU (not shown) that is remotely located from the hardware being controlled by the CPU 152. Some or all of the method of the present disclosure may also be performed in hardware. As such, the disclosure may be implemented in software and executed using a computer system, in hardware as, e.g., an application specific integrated circuit or other type of hardware implementation, or as a combination of software and hardware. The software routine 158 may be executed after the substrate 110 is positioned on the substrate support 108. The software routine 158, when executed by the CPU 152, transforms the general purpose computer into a specific purpose computer (controller) 150 that controls the chamber operation such that the methods disclosed herein are performed.

The disclosure may be practiced using other semiconductor substrate processing systems wherein the processing parameters may be adjusted to achieve acceptable characteristics by those skilled in the art by utilizing the teachings disclosed herein without departing from the spirit of the disclosure.

While the foregoing is directed to embodiments of the present disclosure, other and further embodiments of the disclosure may be devised without departing from the basic scope thereof.

1. A method of selectively depositing a low-k dielectric layer atop a substrate having an exposed silicon surface and an exposed silicon-containing surface, comprising:
(a) growing an organosilane based self-assembled monolayer atop the exposed silicon-containing surface, wherein the organosilane based self-assembled monolayer is thermally stable at a first temperature of greater than about 300 degrees Celsius; and
(b) selectively depositing a low-k dielectric layer atop the exposed silicon surface of the substrate, wherein the organosilane based self-assembled monolayer inhibits deposition of the low-k dielectric layer atop the silicon-containing surface.

2. The method of claim 1, wherein the first temperature is about 300 to about 500 degrees Celsius.

3. The method of claim 1, wherein the silicon-containing surface comprises silicon oxide (SiO2), silicon nitride (SiN), or silicon oxynitride (SiON).

4. The method of claim 1, wherein growing the organosilane based self-assembled monolayer comprises exposing the substrate to a solution comprising an organosilane and a solvent.

5. The method of claim 4, wherein the organosilane comprises a C-8 to C-30 alkyl chain.

6. The method of claim 4, wherein the substrate is rinsed with the solvent after growing the organosilane based self-assembled monolayer.

7. The method of claim 4, wherein the solution comprises the solvent having about 1 millimol to about 10 millimol of organosilane.

8. The method of claim 1, further comprising heating the substrate to a temperature of about 500 to about 1000 degrees Celsius to remove the organosilane based self-assembled monolayer.

9. A method of selectively depositing a layer atop a substrate having an exposed metal surface and an exposed silicon-containing surface, comprising:
(a) growing a first self-assembled monolayer atop the exposed metal surface;
(b) growing a second self-assembled monolayer atop the exposed silicon-containing surface, wherein the second self-assembled monolayer is organosilane based;
(c) heating the substrate to a temperature of about 200 to about 300 degrees Celsius to remove the first self-assembled monolayer from atop the exposed metal surface;
(d) selectively depositing a layer atop the exposed metal surface, wherein the layer is a low-k dielectric layer or a metal layer; and
(e) heating the substrate to a temperature of about 500 to about 1000 degrees Celsius to remove the second self-assembled monolayer from atop the exposed silicon-containing surface.

10. The method of claim 9, wherein depositing the first self-assembled monolayer comprises exposing the substrate to a first solution comprising a solvent and a self-assembled monolayer precursor.

11. The method of claim 10, wherein the self-assembled monolayer precursor comprises C-8 to C-30 chain alkyl thiols, organophosphonic acids, or sulfonic acids.

12. The method of claim 10, wherein the first solution comprises the solvent having about 1 millimol to about 10 millimol of self-assembled monolayer precursor.

13. The method of claim 10, wherein depositing the second self-assembled monolayer comprises exposing the substrate to a second solution comprising an organosilane and a solvent.

14. The method of claim 13, wherein the organosilane comprises C-8 to C-30 alkyl chains.

15. The method of claim 13, wherein the second solution comprises the solvent having about 1 millimol to about 10 millimol of organosilane.

16. The method of claim 1, wherein the low-k dielectric layer has a low-k value in an amount of about 2.5 to about 3.5.

17. The method of claim 9, wherein the low-k dielectric layer has a low-k value in an amount of about 2.5 to about 3.5.

18. A semiconductor substrate comprising:
a first layer comprising a silicon-containing surface and a silicon surface; and
a second layer comprising an organosilane based self-assembled monolayer and a low-k dielectric layer, wherein the organosilane based self-assembled monolayer is disposed atop the silicon-containing surface and the low-k dielectric layer is disposed atop the silicon surface, and wherein the organosilane based self-assembled monolayer is thermally stable at a first temperature of greater than about 300 degrees Celsius.

19. The semiconductor substrate of claim 18, wherein the organosilane based self-assembled monolayer comprises a C-8 to C-30 alkyl chain.

20. The semiconductor substrate of claim 18, wherein the low-k dielectric layer has a low-k value in an amount of about 2.5 to about 3.5.
